(19) United States
(12) Patent Application Publication
(10) Pub. No.: US 2017/0016954 A1
(43) Pub. Date: Jan. 19, 2017

(54) SYSTEMS AND METHODS FOR GENERATING AND PRESERVING VACUUM BETWEEN SEMICONDUCTOR WAFER AND WAFER TRANSLATOR

(71) Applicant: Translarity, Inc., Fremont, CA (US)

(72) Inventors: Nikolai Kalnin, Santa Clara, CA (US); Christopher T. Lane, Los Gatos, CA (US); David Ekstrom, Portland, OR (US); Morgan T. Johnson, Beaverton, OR (US); Douglas A. Preston, McMinnville, OR (US)

(73) Assignee: Translarity, Inc., Fremont, CA (US)

(21) Appl. No.: 15/179,641

(22) Filed: Jun. 10, 2016

Related U.S. Application Data
(60) Provisional application No. 62/230,643, filed on Jun. 10, 2015.
(60) Provisional application No. 62/277,572, filed on Jan. 12, 2016.

(51) Int. Cl. G01R 31/28; G01R 1/04; H01L 21/67; H01L 21/66; H01L 21/683; H01L 21/677

(52) U.S. Cl. CPC G01R 31/2891; H01L 21/6838; H01L 21/677; H01L 21/67242; H01L 22/14; H01L 21/67144; G01R 1/0466

(57) ABSTRACT

Systems and methods for testing semiconductor wafers using a wafer translator are disclosed herein. In one embodiment, an apparatus for testing semiconductor dies on a wafer includes a wafer translator having a wafer-side facing toward the wafer, and an inquiry-side facing away from the wafer-side. The wafer has an active side facing the translator. The apparatus includes a peripheral seal configured to seal a space between the wafer translator and the wafer, and a valve in a fluidic communication with the space between the wafer translator and the wafer.

### CROSS-REFERENCES TO RELATED APPLICATIONS

This application claims the benefit of U.S. Provisional Application No. 62/230,643, filed Jun. 10, 2015, and U.S. Provisional Application No. 62/277,572, filed Jan. 12, 2016, both of which are hereby incorporated by reference in their entirety.

### FIELD OF THE INVENTION

The present invention relates generally to semiconductor test equipment. More particularly, the present invention relates to methods and apparatuses for the removable attachment of a wafer to the test equipment.

### BACKGROUND

Integrated circuits are used in a wide variety of products. Integrated circuits have continuously decreased in price and increased in performance, becoming ubiquitous in modern electronic devices. These improvements in the performance/cost ratio are based, at least in part, on miniaturization, which enables more semiconductor dies to be produced from a wafer with each new generation of the integrated circuit manufacturing technology. Furthermore, the total number of the signal and power/ground contacts on a semiconductor die generally increases with new, more complex die designs.

Prior to shipping a semiconductor die to a customer, the performance of the integrated circuits is tested, either on a statistical sample basis or by testing each die. An electrical test of the semiconductor die typically includes powering the die through the power/ground contacts, transmitting signals to the input contacts of the die, and measuring the resulting signals at the output contacts of the die. Therefore, during the electrical test at least some contacts on the die must be electrically contacted to connect the die to sources of power and test signals.

Conventional test contactors include an array of contact pins attached to a substrate that can be a relatively stiff printed circuit board (PCB). In operation, the test contactor is pressed against a wafer such that the array of contact pins makes electrical contact with the corresponding array of die contacts (e.g., pads or solderballs) on the dies (i.e., devices under test or DUTs) of the wafer. Next, a wafer tester sends electrical test sequences (e.g., test vectors) through the test contactor to the input contacts of the dies of the wafer. In response to the test sequences, the integrated circuits of the tested die produce output signals that are routed through the test contactor back to the wafer tester for analysis and determination whether a particular die passes the test. Next, the test contactor is stepped onto another die or group of dies that are tested in parallel to continue testing till the entire wafer is tested.

In general, an increasing number of die contacts that are distributed over a decreasing area of the die results in smaller contacts spaced apart by smaller distances (e.g., a smaller pitch). Furthermore, a characteristic diameter of the contact pins of the test contactor generally scales with a characteristic dimension of the contact structures on the semiconductor die or the package. Therefore, as the contact structures on the die become smaller and/or have a smaller pitch, the contact pins of the test contactors become smaller, too. However, it is difficult to significantly reduce the diameter and pitch of the contact pins of the test contactor, e.g., because of the difficulties in machining and assembling such small parts, resulting in low yield and inconsistent performance from one test contactor to another. Additionally, the contact pins of the test contactor can be relatively easily damaged because of their small size. Furthermore, precise alignment between the test contactor and the wafer is difficult because of the relatively small size/pitch of the contact structures on the wafer. Once the contact between the test contactor and the wafer is achieved and the wafer is tested, the contacting/testing process must be reliably repeated with the next wafer, and so on.

Accordingly, there remains a need for cost effective test contactors that can scale down in size with the size and pitch of the contact structure on the die.

### BRIEF DESCRIPTION OF THE DRAWINGS

The aspects of the present disclosure can be better understood with reference to the following drawings. The components in the drawings are not necessarily to scale. Instead, emphasis is placed on clearly illustrating the principles of the present disclosure.

FIG. 1A is an exploded view of a portion of a test stack for testing semiconductor wafers in accordance with an embodiment of the presently disclosed technology.

FIG. 1B is a partially schematic, top view of a wafer translator configured in accordance with an embodiment of the presently disclosed technology.

FIG. 1C is a partially schematic, bottom view of a wafer translator configured in accordance with an embodiment of the presently disclosed technology.

FIGS. 2A-2F are partially schematic, side views of a wafer translator engaging with a wafer in accordance with an embodiment of the presently disclosed technology.

FIGS. 3A-3D are partially schematic, cross-sectional views of picking a valve seal in accordance with an embodiment of the presently disclosed technology.

FIGS. 4A-4F are partially schematic, cross-sectional views of placing a valve seal in accordance with an embodiment of the presently disclosed technology.

FIGS. 5A-5E are partially schematic, cross-sectional views of disposing of a valve seal in accordance with an embodiment of the presently disclosed technology.

### DETAILED DESCRIPTION

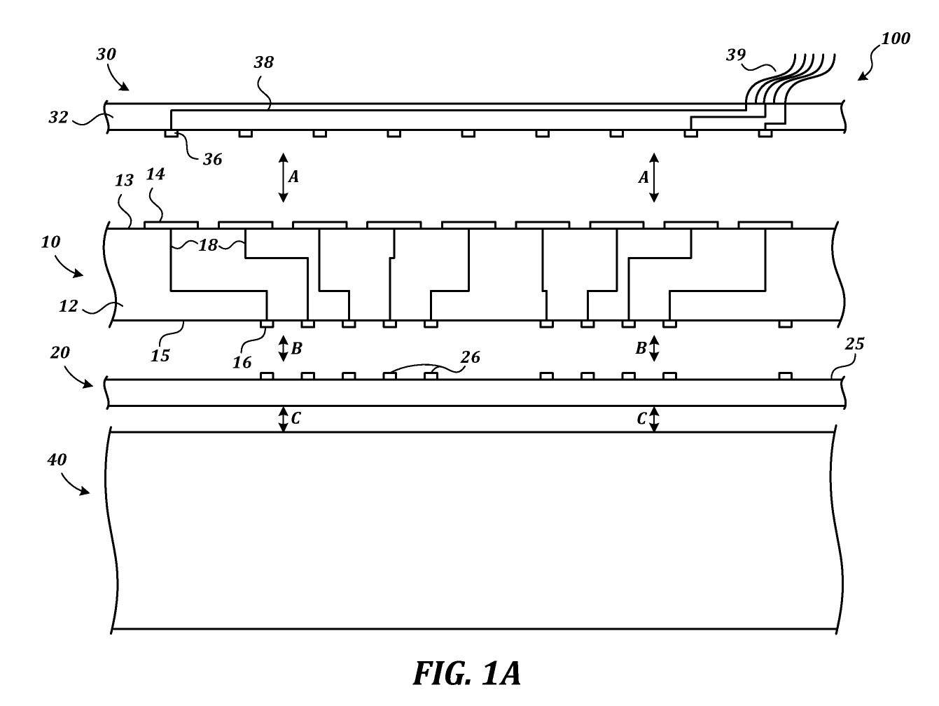

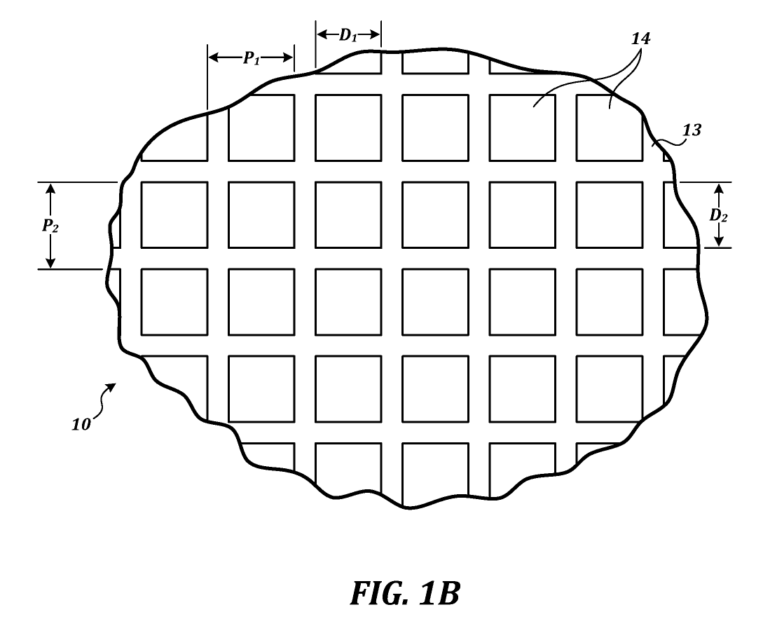

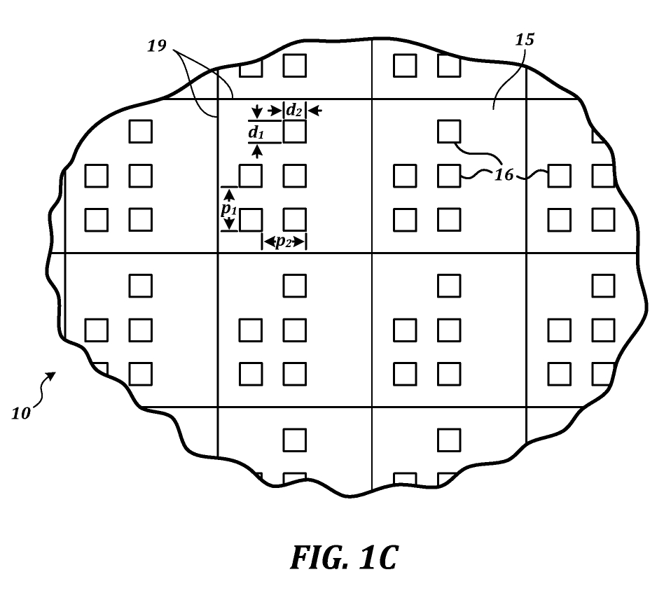

Specific details of several embodiments of representative wafer translators and associated methods for use and manufacture are described below. The wafer translators can be used for testing semiconductor dies on a wafer. The semiconductor dies may include, for example, memory devices, logic devices, light emitting diodes, micro-electro-mechanical-systems, and/or combinations of these devices. A person skilled in the relevant art will also understand that the technology may have additional embodiments, and that the technology may be practiced without several of the details of the embodiments described below with reference to FIGS. 1A-5E.

Briefly described, methods and devices for testing dies on the semiconductor wafers are disclosed. The semiconductor wafers can be produced in different diameters, e.g., 150 mm, 200 mm, 300 mm, 450 mm, etc. The disclosed methods and systems enable operators to test devices having pads, solderballs and/or other contact structures having small sizes and/or pitches. Solderballs, pads, and/or other suitable conductive elements on the dies are collectively referred to herein as “contact structures” or “contacts.” In many embodiments, the technology described in the context of one or more types of contact structures can also be applied to other contact structures.

In some embodiments, a wafer-side of the wafer translator carries the wafer-side contact structures having relatively small sizes and/or pitches (collectively, “scale”). The wafer-side contact structures of the wafer translator are electrically connected to corresponding inquiry-side contact structures having relatively larger sizes and/or pitches at the opposite, inquiry-side of the wafer translator. Therefore, once the wafer-side contact structures are properly aligned to contact the semiconductor wafers, the larger size/pitch of the opposing inquiry-side contact structures enable more robust contact (e.g., requiring less precision). The larger size/pitch of the inquiry-side contact structures may provide more reliable contact and be easier to align against the pins of the test contactor. In some embodiments, the inquiry-side contacts may have mm scale, while the wafer-side contacts have sub-mm or μm scale.

In at least some embodiments, contact between the wafer translator and the wafer is kept by a vacuum in a space between the wafer translator and the wafer. For example, a pressure differential between a lower pressure (e.g., sub-atmospheric pressure) in the space between the wafer translator and the wafer, and a higher outside pressure (e.g., atmospheric pressure) can generate a force over the inquiry-side of the wafer translator resulting in a sufficient electrical contact between the wafer-side contact structures and the corresponding die contacts of the wafer.

Many embodiments of the technology described below may take the form of computer- or controller-executable instructions, including routines executed by a programmable computer or controller. Those skilled in the art will appreciate that the technology can be practiced on computer/controller systems other than those shown and described below. The technology can be embodied in a special-purpose computer, controller, or data processor that is specifically programmed, configured, or constructed to perform one or more of the computer-executable instructions described below. Accordingly, the terms “computer” and “controller” as generally used herein refer to any data processor and can include Internet appliances and hand-held devices (including palm-top computers, wearable computers, cellular or mobile phones, multi-processor systems, processor-based or programmable consumer electronics, network computers, mini computers and the like). Information handled by these computers can be presented by any suitable display medium, including a CRT display or LCD.

The technology can also be practiced in distributed environments, where tasks or modules are performed by remote processing devices that are linked through a communications network. In a distributed computing environment, program modules or subroutines may be located in local and remote memory storage devices. Aspects of the technology described below may be stored or distributed on computer-readable media, including magnetic or optically readable or removable computer disks, as well as distributed electronically over networks. Data structures and transmissions of data particular to aspects of the technology are also encompassed within the scope of the embodiments of the technology.

FIG. 1A is an exploded view of a portion of a test stack 100 for testing semiconductor wafers in accordance with an embodiment of the presently disclosed technology. The test stack 100 can route signals and power from a tester (not shown) to a wafer or other substrate carrying one or more devices under test (DUTs), and transfer the output signals from the DUTs (e.g., semiconductor dies) back to the tester for analysis and determination about an individual DUT's performance (e.g., whether the DUT is suitable for packaging and shipment to the customer). The DUT can be a single semiconductor die or multiple semiconductor dies (e.g., when using a parallel test approach). The signals and power from the tester may be routed through a test contactor 30 to a wafer translator 10, and further to the semiconductor dies on the wafer 20.

In some embodiments, the signals and power can be routed from the tester to the test contactor 30 using cables 39. Conductive traces 38 carried by a test contactor substrate 32 can electrically connect the cables 39 to contacts 36 on the opposite side of the test contactor substrate 32. In operation, the test contactor 30 can contact an inquiry-side 13 of a wafer translator 10 as indicated by arrows A. In at least some embodiments, relatively large inquiry-side contact structures 14 can improve alignment with the corresponding contacts 36 of the test contactor 30. The contact structures 14 at the inquiry-side 13 are electrically connected with relatively small wafer-side contact structures 16 on a wafer-side 15 of the translator 10 through conductive traces 18 of a wafer translator substrate 12. The size and/or pitch of the wafer-side contact structures 16 are suitable for contacting the corresponding die contacts 26 of the wafer 20. Arrows B indicate a movement of the wafer translator 10 to make contact with an active side 25 of the wafer 20. As explained above, the signals and power from the tester can test the DUTs of the wafer 20, and the output signals from the tested DUTs can be routed back to the tester for analysis and a determination as to whether the DUTs are suitable for packaging and shipment to the customer.

The wafer 20 is supported by a wafer chuck 40. Arrows C indicate the direction of the wafer 20 mating with the wafer chuck 40. In operation, the wafer 20 can be held against the wafer chuck 40 using, e.g., vacuum V or mechanical clamping.

FIGS. 1B and 1C are partially schematic, top and bottom views, respectively, of a wafer translator configured in accordance with embodiments of the presently disclosed technology. FIG. 1B illustrates the inquiry-side 13 of the wafer translator 10.

Distances between the adjacent inquiry-side contact structures 14 (e.g., pitch) are denoted P₁ in the horizontal direction and P₂ in the vertical direction. The illustrated inquiry-side contact structures 14 have a width D₁ and a height D₂. Depending upon the embodiment, the inquiry-side contact structures 14 may be squares, rectangles, circles or other shapes. Furthermore, the inquiry-side contact structures 14 can have a uniform pitch (e.g., P₁ and P₂ being equal across the wafer translator 10) or a non-uniform pitch.

FIG. 1C illustrates the wafer-side 15 of the wafer translator 10. In some embodiments, the pitch between the adjacent wafer-side contact structures 16 can be p₁ in the horizontal direction and p₂ in the vertical direction. The width and height of the wafer-side contact structures 16 (“characteristic dimensions”) are denoted as d₁ and d₂. In some embodiments, the wafer-side contact structures 16 can be pins that touch corresponding die contacts on the wafer 20 (FIG. 1A). In general, the size/pitch of the inquiry-side contact structures 14 is larger than the size/pitch of the wafer-side contact structures 16, therefore improving alignment and contact between the test contactor and the wafer translator. The individual dies of the wafer 20 are typically separated from each other by wafer streets 19.

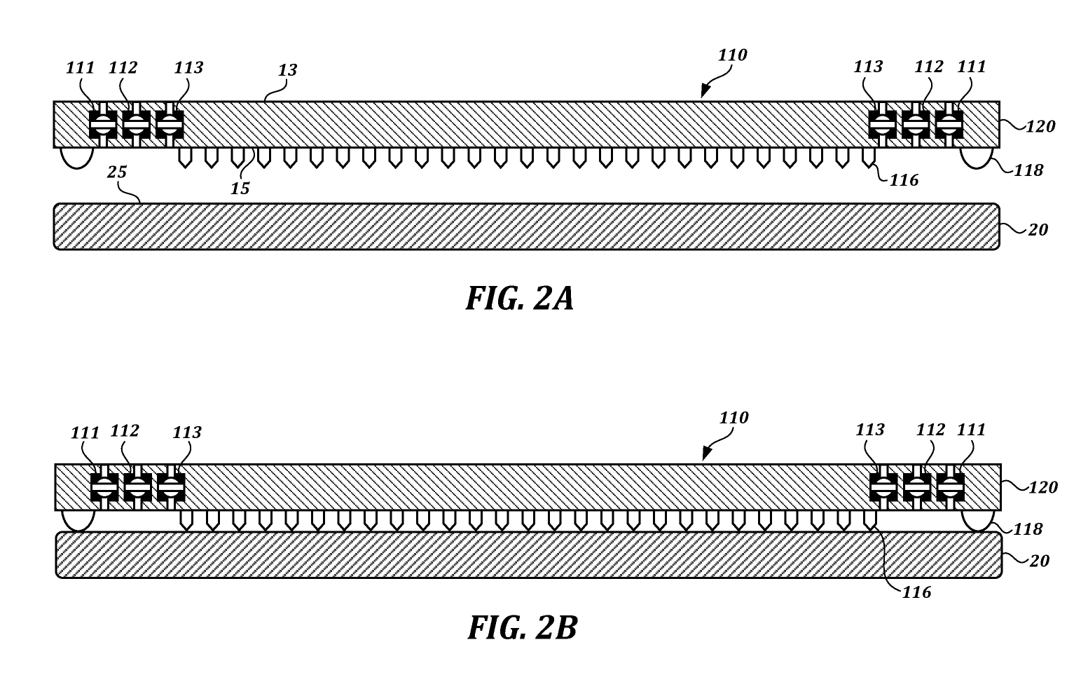

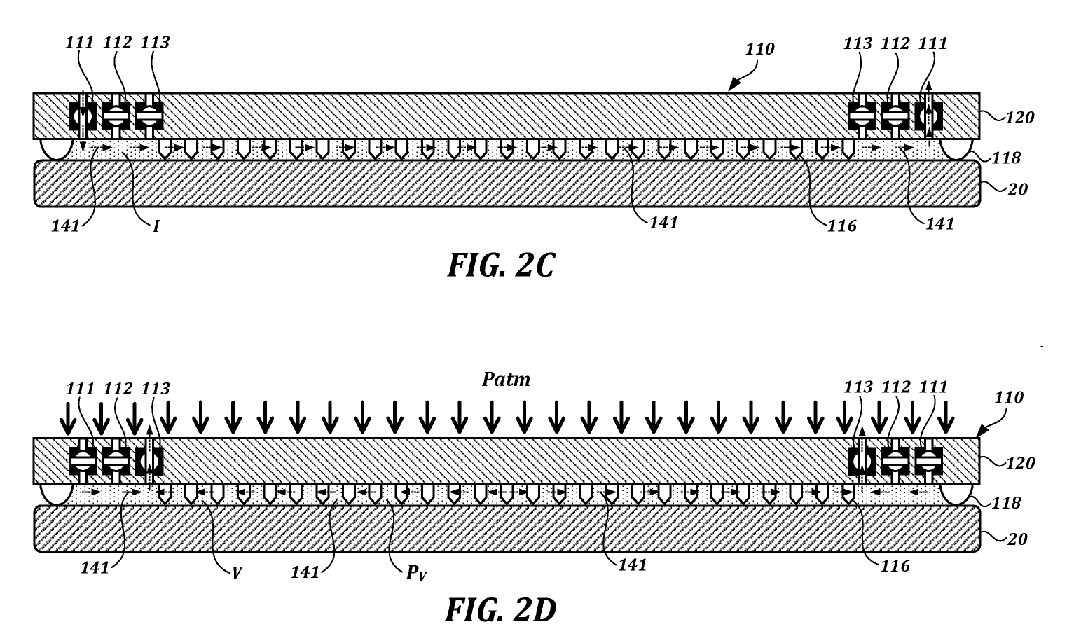

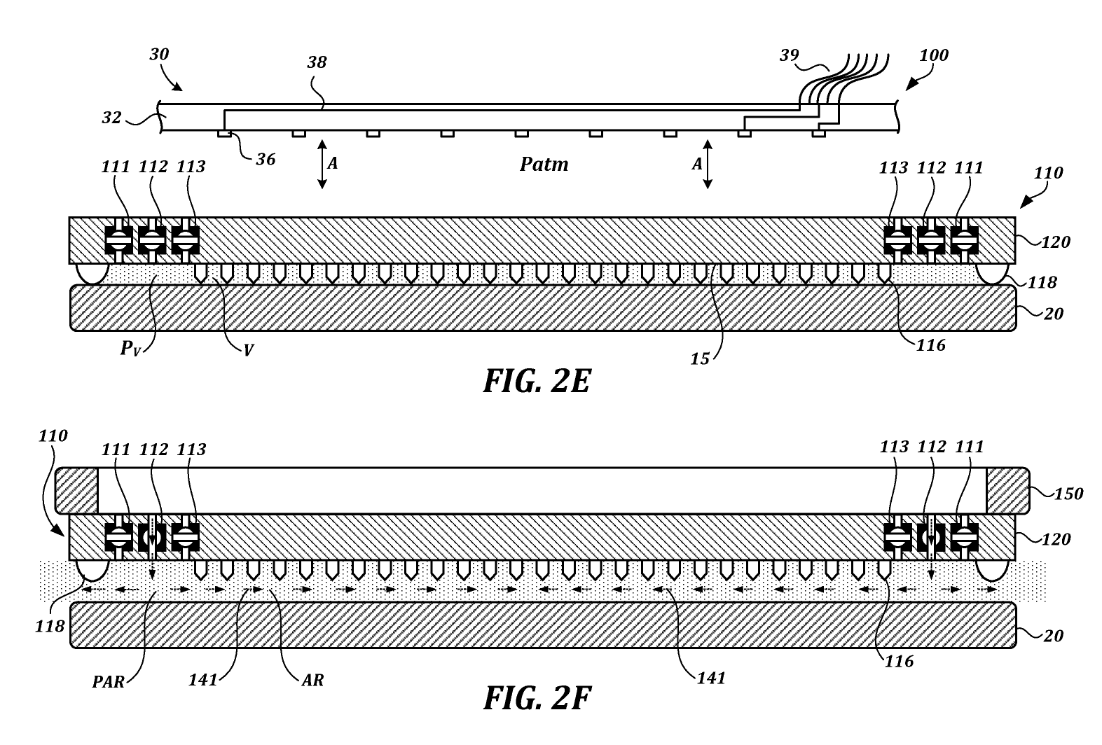

FIGS. 2A-2F are partially schematic, side views of a wafer translator engaging with a wafer in accordance with an embodiment of the presently disclosed technology. FIGS. 2A-2F include the wafer-side 15 of the wafer translator 110 facing the active side 25 of the wafer 20. In some embodiments, a contact force between the wafer translator 110 and the wafer 20 may be controlled by controlling a vacuum between them. As a result, the electrical resistance between the contact structures 116 and the die contacts on the wafer 20 can also be controlled. Additionally, the contact may be improved if the vacuum includes an inert gas that, for example, reduces or slows down the oxidation of the contact structures of the wafer translator 110 and the wafer 20. Furthermore, in at least some embodiments, after the testing the vacuum should be gradually reduced (i.e., the pressure is brought back to an atmospheric or higher pressure) to facilitate a disengagement between the wafer translator 110 and the wafer.

FIG. 2A shows the wafer translator 110 having inert gas valves 111, air supply valves 112 and vacuum valves 113. In some embodiments, the valves may be distributed radially at a periphery of a wafer translator substrate 120 to, for example, avoid interfering with the wafer-side contact structures 116 of the wafer translator 110, and the corresponding die contacts on the wafer 20. In some embodiments, the valves may be configured outside of the wafer translator substrate 120 for easier opening and closing of the valves, and then connected to the space between the wafer translator 110 and the wafer 20 with hoses or pipes with the corresponding openings in the wafer translator 110.

FIG. 2B shows the contact structures 116 of the wafer translator 110 in contact with the active side of the wafer 20. At this step, a peripheral seal 118 contacts the wafer 20 to seal off the outside environment from the space between the wafer translator 110 and the wafer 20. In some embodiments, the wafer translator 110 may extend beyond the outer outline of the wafer 20, and the peripheral seal 118 may contact the wafer chuck 40 (not shown). In some embodiments, for example, when the peripheral seal 118 contacts the wafer chuck 40, the inert gas, the air supply and/or the vacuum may be supplied through the wafer chuck 40. In some embodiments, the peripheral seal 118 can be an O-ring or a lip seal.

FIG. 2C shows the wafer translator 110 in contact with the wafer 20. The inert gas valves 111 are open to let an inert gas I into the space between the wafer translator 110 and the wafer 20. The inert gas I may flow as shown by arrows 141 from one inert gas valve to another to facilitate purging of the air from the space between the wafer translator 110 and the wafer 20, and replacing the air with the inert gas. The inert gas I may be supplied from tanks (not shown). In some embodiments, the inert gas I may be nitrogen. As explained above, inert gas generally reduces or slows down the oxidation of the contact structures of the wafer translator 110 and the wafer 20, especially if the wafer translator 110 and the wafer 20 remain in contact for a prolonged period of time. The peripheral seal 118 may prevent or at least reduce the escape of the inert gas.

FIG. 2D shows the wafer translator 110 in contact with the wafer 20. At this step, one or more vacuum valves 113 are opened, and the inert gas I is vacuumed from the space between the wafer translator 110 and the wafer 20. In some embodiments, vacuum pumps or vacuum tanks (not shown) may be the sources of a vacuum V. The vacuum pumps that are sufficiently compact, e.g., MEMS based vacuum pumps, may be integrated with the wafer translator 110. For example, the vacuum valve 113 may be a combination of the MEMS based vacuum pump and the vacuum valve. Because of the pressure differential between a pressure Pv between the wafer translator 110 and the wafer 20, and an outside pressure Patm, the contact force between the wafer-side contact structures 116 and the dies of the wafer 20 is increased. In some embodiments, the required contact force may be controlled by controlling the value of Pv. In some embodiments, the outside pressure Patm may be higher or lower than the atmospheric pressure, provided, however, that the outside pressure Patm is higher than the pressure Pv between the wafer translator 110 and the wafer 20. The peripheral seal 118 facilitates evacuation of the inert gas I, and prevents or at least reduces an inflow of the outside air into the space between the wafer translator 110 and the wafer 20. The wafer translator 110 and the peripheral seal 118 may be brought to a close proximity to the wafer 20 (or to a close proximity to the chuck 40 if the wafer translator extends beyond the outline of the wafer 20) in a controlled manner by releasing excess gas at the periphery of the wafer translator 110, and contacting the wafer 20 (or the wafer chuck 40) when the system is about to be switched to the vacuum.

FIG. 2E shows the wafer translator 110 in contact with the wafer 20. At this step, the valves 111, 112 and 113 are closed, and the vacuum V is maintained in the space between the wafer translator 110 and the wafer 20 at a pressure Pv. In at least some embodiments, the pressure differential between the pressures Pv and Patm provides required contact force between the wafer-side contact structures 116 and the dies of the wafer 20. In some embodiments, the test contactor 30 contacts the inquiry-side of the wafer translator 110, and the test signals/power from the tester are transmitted to the dies on the wafer 20 through the wafer translator 110. In some embodiments, the wafer translator/wafer assembly may be stored for the subsequent tests.

FIG. 2F shows the air supply valves 112 that are open to a source of outside air AR, for example the atmosphere or pressurized air. The air enters the space between the wafer translator 110 and the wafer 20 to raise the pressure from Pv to P_{AR}. The pressure P_{AR} can be either generally the same as the Patm, or the pressure P_{AR} can be higher than the Patm to facilitate separation of the wafer translator 110 and the wafer 20. In some embodiments, the pressure P_{AR} is reached gradually or in steps to avoid uneven loading of the wafer translator 110. The wafer translator 110 can be moved away from the wafer 20 by a wafer-translator chuck 150. In some embodiments, the tested wafer 20 can be forwarded to further processing steps (e.g., die singulation, die packaging, etc.); another wafer can be mated with the wafer translator 110; and the cycle is repeated.

A person of ordinary skill would recognize that variations are possible with the illustrated sequence of FIGS. 2A-2E. For example, a smaller or greater number of valves may be carried by the wafer translator. For example, the air supply valves 112 and the vacuum valves 113 may be combined. Furthermore, instead of, for example, multiple air supply valves 112 distributed over the vacuum translator 110, a single air supply valve 112 may be used.

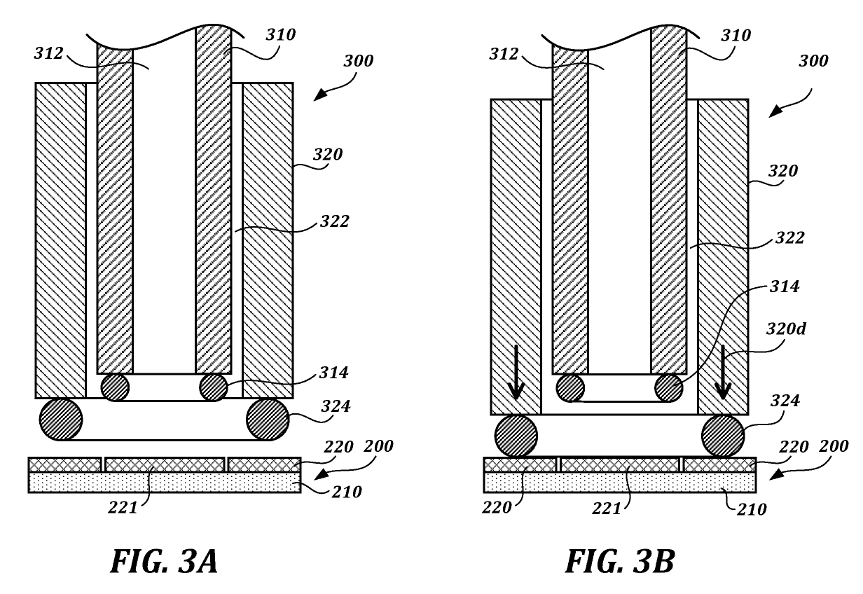

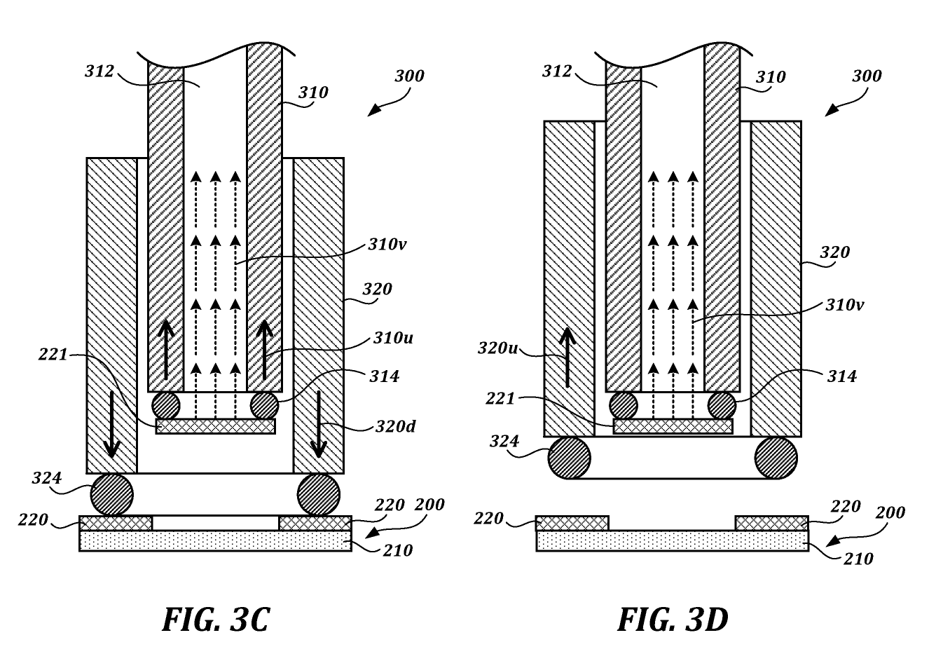

FIGS. 3A-3D are partially schematic, cross-sectional views of picking a valve seal 221 in accordance with an embodiment of the presently disclosed technology. In some embodiments, one or more valves 111-113 may be configured as an opening that is covered by the valve seal 221 to preserve, e.g., vacuum between the wafer and the wafer translator. In some embodiments, a relatively simple valve seal 221 may suffice to preserve the vacuum between the wafer and the wafer translator for relatively long time, e.g., several days or weeks.

FIG. 3A is a partially schematic, cross-sectional view of a pick-and-place (PNP) mechanism 300 and a valve seal tray 200. The valve seal 221 may be made by pre-cutting a valve seal sheet 220 into shapes, e.g., circular, rectangular, oval, etc. The valve seal 221 may be made of polyamide, mylar, glass, rubber, plastic, or other materials. In some embodiments, the side of the valve seal 221 that faces away from the PNP mechanism 300 may be adhesive to facilitate the adhesion with the wafer translator. In some embodiments, the adhesive may be applied at a periphery of the valve seal 221. The valve seal 221 can be carried by a valve seal substrate 210. One valve seal 221 is illustrated in FIG. 3A, but the valve seal sheet may include multiple valve seals 221. The PNP mechanism 300 includes an inner tube 310 and an outer tube 320. In some embodiments, the inner tube 310 and the outer tube 320 may be concentric. The inner tube 310 and the outer tube 320 carry an inner gasket 314 and an outer gasket 324, respectively. In some embodiments, the inner and/or outer gaskets 314/324 may be O-rings or lip seals.

FIG. 3B shows the PNP mechanism 300 engaged with the valve seal tray 200. In this step, the outer tube 320 moved in a downward direction 320d. As a result, the outer gasket 324 is pressed against the valve seal sheet 220. In some embodiments, a contact between the outer gasket 324 and the valve seal sheet 220 may hermetically seal the outside environment from a lumen 322 of the outer tube 320.

FIG. 3C shows the inner gasket 314 engaged with the valve seal 221. A vacuum 310v in an inner lumen 312 can hold the valve seal 221 securely attached to the inner gasket 314. In this step, the inner tube 310 moves in an upward direction 310u, while outer gasket 324 of the outer tube 320 still maintains contact with the valve seal sheet 220.

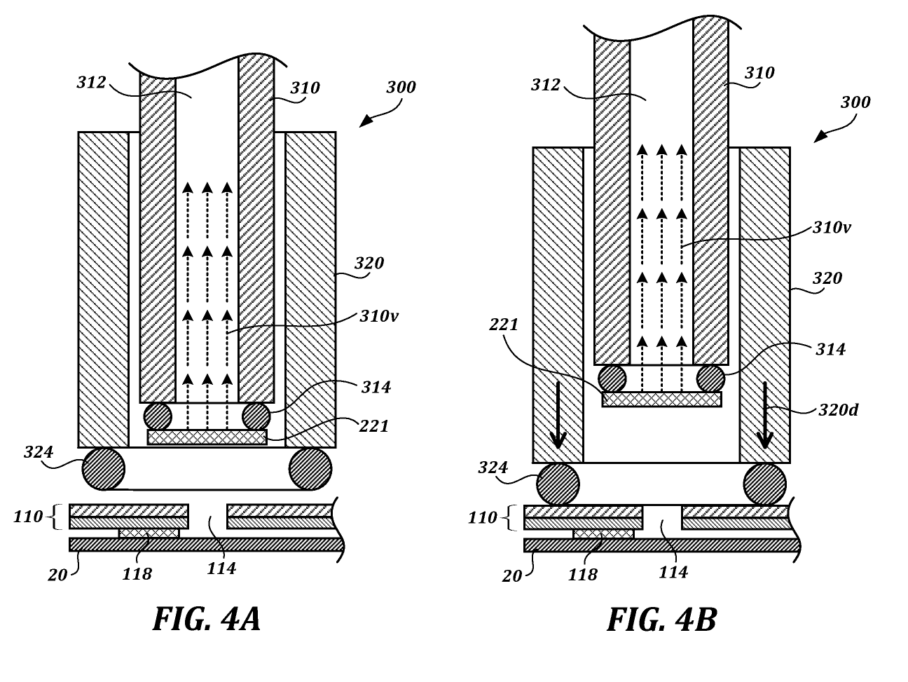

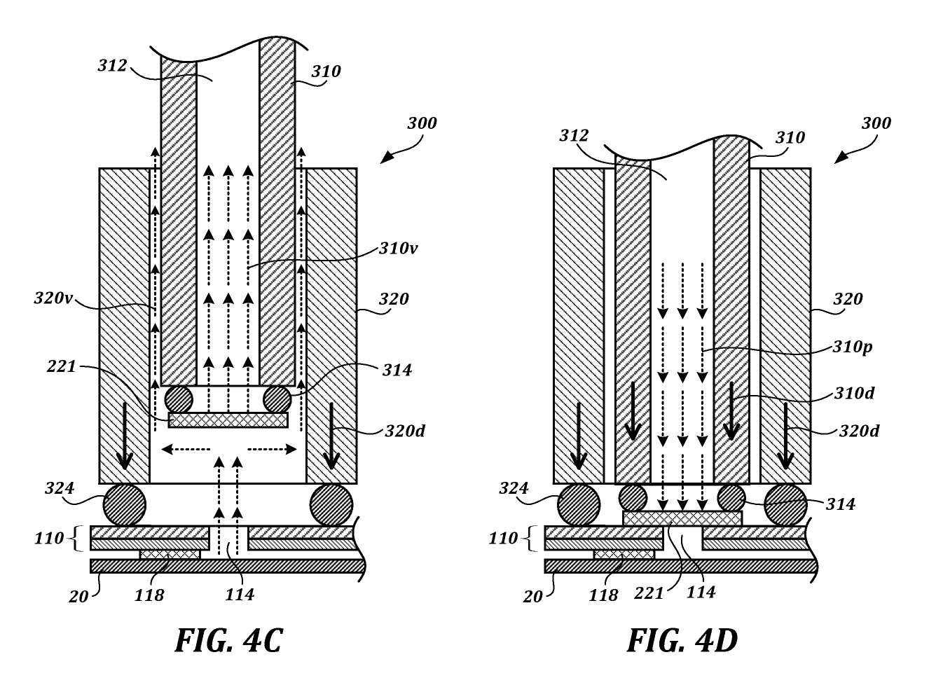

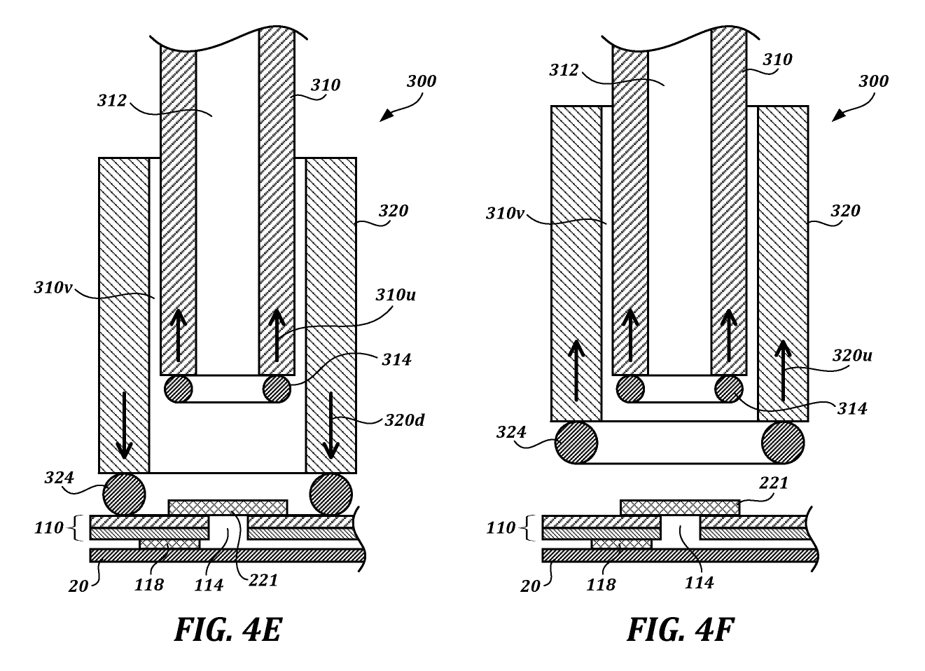

FIG. 3D shows the outer tube 320 that moved in an upward direction 320u to disengage with the valve seal sheet 220. The vacuum 310v still holds the valve seal 221 attached to the inner gasket 314. In some embodiments, the vacuum 310v may be provided from a vacuum tank or a vacuum pump (not shown). After this step, the PNP mechanism 300 can place the valve seal 221 on the openings of the wafer translator, as explained below with reference to FIGS. 4A-4F.

FIGS. 4A-4F are partially schematic, cross-sectional views of placing the valve seal 221 in accordance with an embodiment of the presently disclosed technology. In at least some embodiments, the valve seal 221 may cover an opening 114 (e.g., a valve) in the wafer translator 110 to, for instance, preserve the vacuum between the wafer translator 110 and the wafer 20. One opening 114 is illustrated in FIGS. 4A-4F, but in other embodiments the wafer translator 110 may include additional openings. The peripheral seal 118 seals the space between the wafer translator 110 and the wafer 20 to prevent escaping of, e.g., the inert gas. The illustrated wafer translator 110 includes multiple layers (e.g., conductive or insulating layers).

FIG. 4A is a partially schematic, cross-sectional view of a pick-and-place (PNP) mechanism 300 over the wafer translator 110 and the wafer. The outer gasket 324 is positioned against the opening 114 in the wafer translator 110. The vacuum 310v keeps the valve seal 221 against the inner gasket 314.

FIG. 4B shows the outer tube 320 that moved toward the wafer translator 110 in the downward direction 320d. At this step, the outer gasket 324 seals the space between the opening 114 in the wafer translator and the outer tube 320.

FIG. 4C shows the evacuation of the gas in the space between the wafer translator 110 and the wafer 20. In the illustrated embodiment, a vacuum 320v is applied to the space between the outer tube 320 and the inner tube 310. The vacuum 320v evacuates the gas (e.g., an inert gas) while the outer gasket 324 seals away the outer atmosphere.

FIG. 4D shows the valve seal 221 that covers the opening 114. A pressure 310p (e.g., an above-atmospheric pressure) is applied in the inner tube 310 to release the valve seal 221 from the inner gasket 314. In some embodiments, the valve seal 221 may have an adhesive for adhesion with the wafer translator 110. At this step, the vacuum between the wafer translator 110 and the wafer 20 is at least partially sealed.

FIG. 4E shows the inner tube 310 that moved away in the upward direction 310u away from the wafer translator 110. The valve seal 221 remains on the wafer translator 110 to seal the opening 114.

FIG. 4F shows the outer tube 320 moved away in the upward direction 320u away from the wafer translator 110. In some embodiments, the valve seal 221 can seal the vacuum for relatively long period of time, e.g., days or weeks.

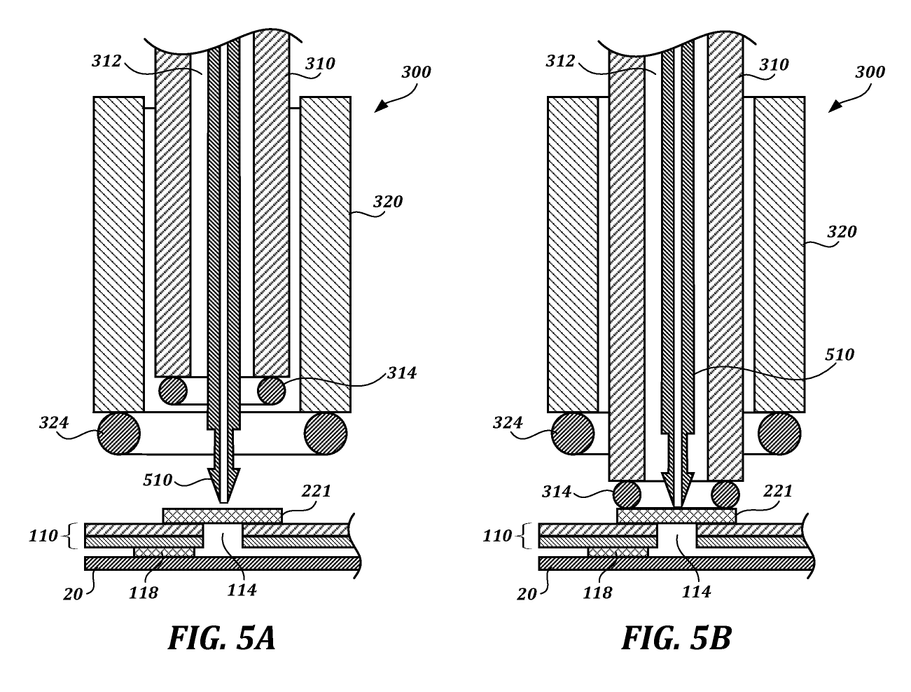

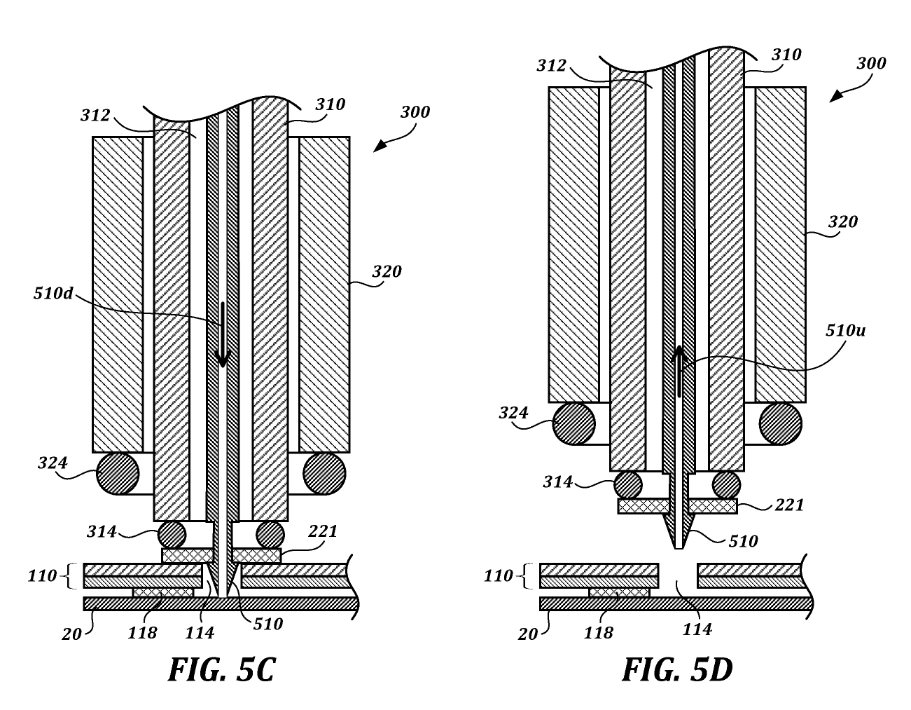

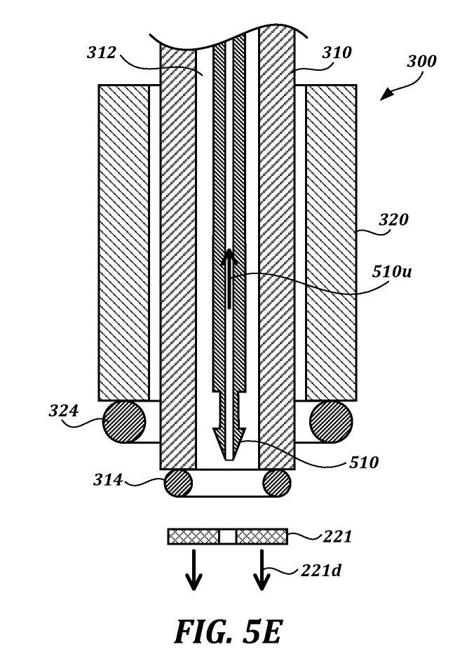

FIGS. 5A-5E are partially schematic, cross-sectional views of disposing of the valve seal 221 in accordance with an embodiment of the presently disclosed technology. In some embodiments, after the testing of the wafer 20 has been completed, the vacuum between the wafer translator 110 and the wafer 20 can be released, the wafer 20 may be forwarded to the subsequent processing steps (e.g., die singulation), and the wafer translator 110 may engage with the next wafer.

FIG. 5A shows the PNP mechanism 300 that includes a remover 510 positioned over the valve seal 221. The illustrated remover 510 includes a tip configured to penetrate the valve seal 221. The remover 510 may be actuated by an actuator (e.g., a pneumatic or an electric actuator). The remover 510 may be concentric with the inner tube 310 and/or the outer tube 320.

FIG. 5B shows the inner gasket 314 engaged with the valve seal 221. In some embodiments, the pressure from the inner gasket 314 may keep the valve seal 221 tensioned as the remover 510 penetrates the valve seal 221.

FIG. 5C shows the valve seal 221 penetrated by the remover 510 that moved in a downward direction 510d. At this step, the vacuum in the space between the wafer translator 110 and the wafer 20 is released through a lumen in the remover 510.

FIG. 5D shows the remover 510 that was moved in an upward direction 510u off the wafer translator 110 to remove the valve seal 221 from the opening 114. In some embodiments, the remover 510 may lightly press the valve seal 221 against the inner gasket 314 to, for example, keep the valve seal 221 more stable.

FIG. 5E shows the valve seal 221 that is removed from the remover 510 as the remover 510 retracted in the upward direction 510u. In some embodiments, the valve seal 221 can be discarded in a downward direction 221d.

From the foregoing, it will be appreciated that specific embodiments of the technology have been described herein for purposes of illustration, but that various modifications may be made without deviating from the disclosure. Moreover, while various advantages and features associated with certain embodiments have been described above in the context of those embodiments, other embodiments may also exhibit such advantages and/or features, and not all embodiments need necessarily exhibit such advantages and/or features to fall within the scope of the technology. Accordingly, the disclosure can encompass other embodiments not expressly shown or described herein.

The embodiments of the invention in which an exclusive property or privilege is claimed are defined as follows:

1. An apparatus for testing semiconductor dies on a wafer, comprising:
a wafer translator having a wafer-side facing toward the wafer, and an inquiry-side facing away from the wafer-side;
the wafer having an active side facing the translator;
a peripheral seal configured to seal a space between the wafer translator and the wafer; and
a valve in a fluidic communication with the space between the wafer translator and the wafer.

2. The apparatus of claim 1, wherein the valve is a first valve configured for supplying an inert gas, the apparatus further comprising a second valve configured for evacuating the inert gas from the space between the wafer translator and the wafer.

3. The apparatus of claim 2, further comprising a third valve in the fluidic communication configured for supplying air to the space between the wafer translator and the wafer.

4. The apparatus of claim 3, wherein at least one of the first, the second, and the third valve is a MEMS based valve.

5. The apparatus of claim 4, further comprising a MEMS based pump integrated with the MEMS based valve.

6. The apparatus of claim 1, wherein the valve is configured at least partially within a wafer translator substrate.

7. The apparatus of claim 1, wherein the valve is configured apart from the wafer translator.

8. The apparatus of claim 1, wherein the valve is an opening in the wafer translator, the apparatus further including a valve seal for sealing the opening.

9. The apparatus of claim 1, wherein the valve seal includes an adhesive layer facing the wafer translator.

10. The apparatus of claim 2, further comprising a test contactor facing the inquiry-side of the wafer translator.

11. The apparatus of claim 1, wherein the wafer-side of the wafer translator carries contact structures having a first scale, and the inquiry-side of the wafer translator carries the contact structures having a second scale, wherein the first scale is smaller than the second scale.

12. A method for testing semiconductor dies on a wafer, comprising:
positioning the wafer to face a wafer-side of a wafer translator, the wafer translator having an inquiry-side facing away from the wafer-side;
sealing a space between the wafer translator and the wafer with a peripheral seal;
evacuating a gas from the space between the wafer translator and the wafer to generate a vacuum; and
sealing the vacuum.

13. The method of claim 12, wherein the gas is an inert gas.

14. The method of claim 12, wherein the gas is evacuated through a first valve, the method further comprising providing the gas through a second valve into the space between the wafer translator and the wafer prior to evacuating the gas.

15. The method of claim 12, wherein at least one of the first and the second valve is a MEMS based valve.

16. The method of claim 12, wherein a MEMS based pump is integrated with the MEMS based valve.

17. The method of claim 14, wherein the gas is a first gas, the method further comprising reducing the vacuum by providing a second gas into the space between the wafer translator and the wafer.

18. The method of claim 12, further comprising contacting the inquiry-side of the wafer translator with a test contactor.

19. The apparatus of claim 12, wherein the wafer-side of the wafer translator carries contact structures having a first scale, and the inquiry-side of the wafer translator carries the contact structures having a second scale, wherein the first scale is smaller than the second scale.

20. A method for testing semiconductor dies on a wafer, comprising:
positioning the wafer to face a wafer-side of a wafer translator, the wafer translator having an inquiry-side facing away from the wafer-side;
positioning a pick-and-place (PNP) mechanism over a valve seal carried by a tray;
sealing an opening in the wafer translator with a gasket of the PNP mechanism;
evacuating a gas from a space between the wafer translator and the wafer at least partially through the PNP mechanism to generate a vacuum; and
transferring the valve seal from the tray to the opening to seal the opening in the wafer translator.

21. The method of claim 20, wherein the PNP mechanism includes an inner tube configured to hold the valve seal and an outer tube configured to seal the opening in the wafer translator while evacuating the gas from the space between the wafer translator and the wafer.

22. The method of claim 21, further comprising removing the valve seal from the opening in the wafer translator using a remover positioned at least partially inside the inner tube of the PNP mechanism.

23. The method of claim 20, wherein the wafer translator and the wafer are separated by a peripheral seal.

24. The method of claim 20, further comprising testing the semiconductor dies.

25. The method of claim 20, wherein the gas is an inert gas.

26. The method of claim 20, wherein the wafer-side of the wafer translator carries contact structures having a first scale, and the inquiry-side of the wafer translator carries the contact structures having a second scale, wherein the first scale is smaller than the second scale.
